(19) United States
(12) Patent Application Publication
(10) Pub. No.: US 2008/0135970 A1
(43) Pub. Date: Jun. 12, 2008

(54) High Voltage Shottky Diodes

(75) Inventors: Yong-don Kim, Gyeonggi-do (KR); Sun-hyun Kim, Gyeonggi-do (KR); Jung-soo Yoo, Gyeonggi-do (KR); Ji-hoon Cho, Seoul (KR); Seung-teck Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/947,066

(22) Filed: Nov. 29, 2007

(30) Foreign Application Priority Data
Dec. 7, 2006 (KR) 2006-124064

(51) Int. Cl. H01L 29/872

(52) U.S. Cl. 257/471; 257/E29.338

(57) ABSTRACT

High voltage schottky diodes are provided including a first conductivity type semiconductor substrate and a second conductivity type well region defined by the substrate. A first conductive film is provided on a surface of the substrate including the well. A conductive electrode is provided on at least one side of the first conductive film above the substrate including the well. An insulating film is provided between the conductive electrode and the substrate. A cathode contact region is provided outside the conductive electrode remote from the first conductive film. The cathode contact region is doped with high concentration impurities having a second conductive type.

### CLAIM OF PRIORITY

This application is related to and claims priority from Korean Patent Application No. 10-2006-0124064, filed on Dec. 7, 2006, in the Korean Intellectual Property Office, the disclosure of which is hereby incorporated herein by reference as if set forth in its entirety.

### FIELD OF THE INVENTION

The present invention generally relates to diodes and, more particularly, to schottky diodes.

### BACKGROUND OF THE INVENTION

A schottky diode uses rectification occurring at the interface between a metal and a semiconductor. The schottky diode is a majority carrier device in which a current across the schottky diode is determined by emission of majority carriers going over a potential barrier. However, researcher have focused on reducing or even preventing a leakage current from occurring at a reverse voltage in the schottky diode.

Referring to FIG. 1, a cross-section illustrating a conventional schottky diode will be discussed. As illustrated in FIG. 1, an impurity region 12 is formed at a side and a bottom of a field oxide layer 14 defining an active region in a substrate 10. The impurity region 12 is doped with an opposite impurity ions having a conductivity type opposite the substrate 10. A metal layer 16, such as a silicide, is formed on a surface of the active region so as to form a schottky junction with the substrate 10. The field oxide layer 14 may have a conventional local oxidation isolation (LOCOS) structure or a conventional shallow trench isolation (STI) structure having a different permittivity with the substrate 10. Such a structure in which the field oxide layer 14 is merged with the low concentration p-type doped region 12 to reduce the likelihood or even prevent current leakage is called a merged p-type schottky (MPS) structure.

FIG. 2A is a cross-section illustrating the structure of a conventional high-voltage schottky diode. FIG. 2B is an equivalent circuit diagram illustrating a current flow of the schottky diode of FIG. 2A. Referring to FIG. 2A, an n⁻ well 52 is formed on a p-type substrate 50, and a field oxide layer 14 is formed in the n⁻ well 52 to define an active region. An anode electrode 16 is formed on a surface of the active region formed between the field oxide layer 14. A cathode electrode 56 is located on the other side of the field oxide layer 14. The cathode electrode 56 is formed on an n⁺ doped cathode contact region 54. In addition, the p⁻ impurity region 12 is formed at an anode side and a bottom of the field oxide layer 14.

Referring to FIG. 2B, a schottky diode (D) having an MPS structure additionally includes a parasitic transistor (Q1), a pinched resistor (R1), and a drift resistor (R2). The pinched resistor (R1) is formed by the impurity region 12 that reduces an area through which a current flows. The drift resistor (R2) represents that the impurity region 12 interferes with a current flow going through the n⁻ well 52. The parasitic transistor (Q1) is formed of the p⁻ impurity region 12, the n⁻ well 52, and the p-type substrate 50.

When the conventional schottky diode illustrated in FIG. 2A is forward biased, the parasitic transistor (Q1) can be turned on by a voltage drop caused by a turn-on voltage from about 0.3 to about 0.5V and the pinched resistor (R1). When the parasitic transistor (Q1) is turned on, cross talk effects may occur in an integrated circuit including the schottky diode. The cross talk effects may result in malfunctions of the integrated circuit. Furthermore, a current driving capability may be decreased by the pinched resistor (R1).

### SUMMARY OF THE INVENTION

Some embodiments of the present invention provide high voltage schottky diodes including a first conductivity type semiconductor substrate and a second conductivity type well region defined by the substrate. A first conductive film is provided on a surface of the substrate including the well. A conductive electrode is provided on at least one side of the first conductive film above the substrate including the well. An insulating film is provided between the conductive electrode and the substrate. A cathode contact region is provided outside the conductive electrode remote from the first conductive film. The cathode contact region is doped with high concentration impurities having a second conductive type.

In further embodiments of the present invention, the first conductive film may include a metal silicide. In certain embodiments of the present invention, a second conductive film is provided on the conductive electrode. The first and second conductive films may be anode electrodes having a similar electric potential value. The first and second conductive films may include a metal silicide.

In still further embodiments of the present invention, the conductive electrode may include polysilicon.

In some embodiments of the present invention, a cathode electrode is provided on the cathode contact region.

In still further embodiments of the present invention, a first doped region may be in the well under the cathode contact region and is doped with impurities having the second conductive type such that a doping concentration of the first doped region is higher than that of the well and lower than that of the cathode contact region.

In some embodiments of the present invention, a second doped region may be provided in the well under the first conductive film and the conductive electrode. The second doped region is doped with impurities having the second conductive type such that a doping concentration of the second doped region is higher than that of the well and lower than that of the cathode contact region.

In further embodiments of the present invention, the doping concentration of the second doped region may be lower than 1018 atoms/cm².

In still further embodiments of the present invention, an insulating layer is provided between the conductive electrode and the cathode contact region. The insulating layer may include a silicon oxide layer.

In some embodiments of the present invention, an isolation layer may be provided isolating the well and the substrate from the cathode contact region. A substrate contact region may be provided outside the isolation layer at an opposite side of the cathode contact region in order to expose the substrate. The substrate contact region may be doped with high concentration impurities having the first conductivity type.

Further embodiments of the present invention provide high-voltage schottky diodes including a first conductivity type semiconductor substrate and a second conductivity type well defined on an upper portion of the substrate. A first conductive film is provided on a surface of the substrate including the well. A conductive electrode is provided on at least both sides of the first conductive film above the substrate including the well. An insulating film is provided between the conductive electrode and the substrate. A cathode contact region is provided outside the conductive electrode remote from the first conductive film. The cathode contact region is doped with high concentration impurities having the second conductivity type. An insulating layer is provided on the substrate between the conductive electrode and the cathode contact region for device isolation.

In still further embodiments of the present invention, a second conductive film may be provided on the conductive electrode. The first and second conductive films may be anode electrodes having a similar electric potential value. The first and second conductive films may include a metal silicide.

In some embodiments of the present invention, the conductive electrode may include polysilicon. A first doped region may be provided is in the well under the cathode contact region and may be doped with impurities having the second conductivity type such that a doping concentration of the first doped region is higher than that of the well and lower than that of the cathode contact region.

In further embodiments of the present invention, a second doped region may be provided in the well under the first conductive film and the conductive electrode. The second doped region may be doped with impurities having the second conductivity type such that a doping concentration of the second doped region is higher than that of the well and lower than that of the cathode contact region

### BRIEF DESCRIPTION OF THE DRAWINGS

FIG. 1 is a cross-section illustrating a conventional schottky diode.

FIG. 2A is a cross-section illustrating a conventional structure for a high-voltage schottky diode.

FIG. 2B is an equivalent circuit diagram illustrating a current flow of FIG. 2A.

FIG. 3A is a cross-section illustrating a structure for a high-voltage schottky diode according to some embodiments of the present invention.

FIG. 3B is an equivalent circuit diagram illustrating a current flow of FIG. 3A.

FIG. 4 is a partial sectional view illustrating the reason why an insulating layer described in FIG. 3A should be present.

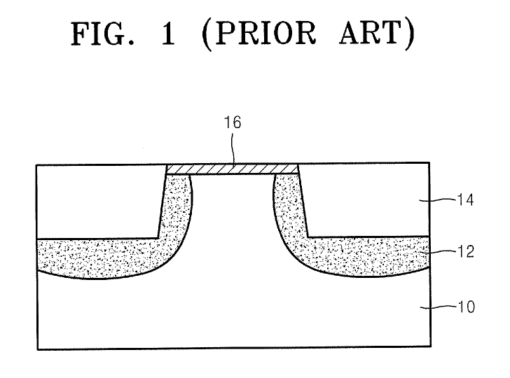

### DETAILED DESCRIPTION OF EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that although the terms first and second are used herein to describe various elements, these elements should not be limited by these terms. These terms are only used to distinguish one element from another element.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a discrete change from implanted to non-implanted regions. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning in other words consistent with their meaning in the context of the relevant art and this specification and will not be interpreted in an idealized or overly formal sense unless expressly so defined herein.

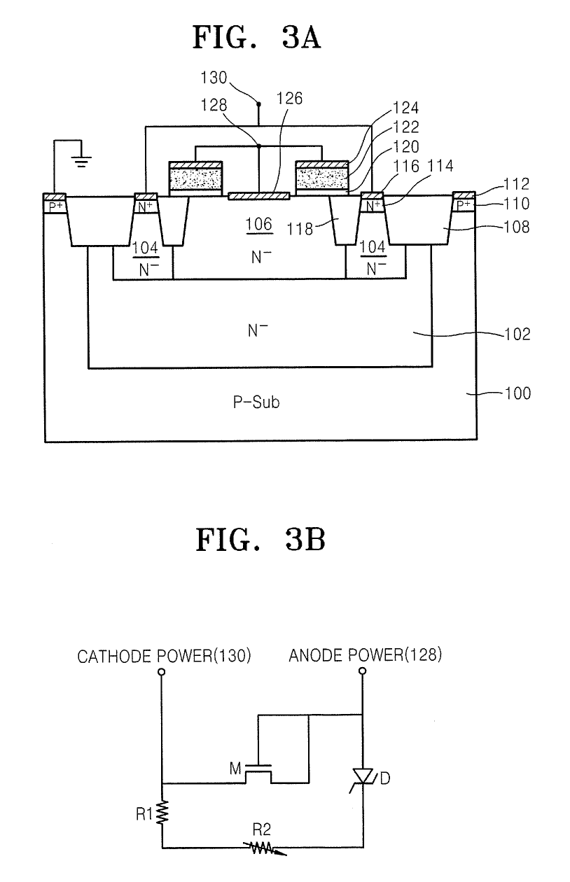

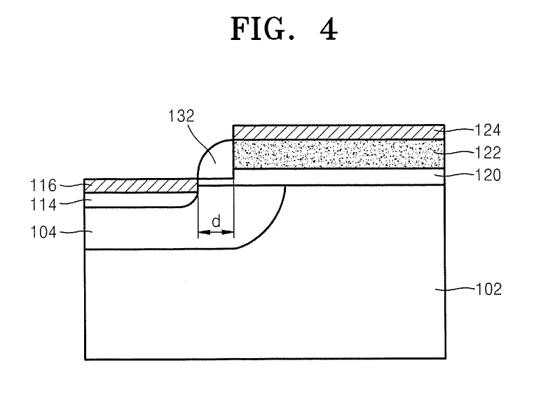

As will be discussed below with respect to FIGS. 3A through 4, a schottky diode is provided without a conventional impurity region according to some embodiments of the present invention. As discussed herein, the structure removes a parasitic transistor and reduces a pinched resistor and a drift resistor. A structure for a schottky diode includes the schottky diode and components for improving characteristics of the schottky diode.

FIG. 3A is a cross-section illustrating a structure for a high-voltage schottky diode according to some embodiments of the present invention. FIG. 3B is an equivalent circuit diagram illustrating a current flow of the schottky diode illustrated in FIG. 3A.

Referring to FIGS. 3A and 3B, a second conductive type well, for example, an n-type well 102 is formed on an upper portion of a first conductive type substrate, for example, a p-type semiconductor substrate 100. The n-type well 102 is extended at a predetermined depth from a bottom of an isolation layer 108 defining an active region. The schottky diode (D) of the present invention is formed at the active region between the isolation layer 108. The schottky diode (D) includes a junction of the n-type well 102 and a first conductive film 126. The first conductive film 126 may be, for example, a metal silicide. The metal silicide may be formed by a conventional CMOS process and, thus, the schottky diode (D) can be manufactured by the CMOS process. An n⁺ cathode contact region 114 contacts a side of the active region from the isolation layer 108.

A cathode electrode 116 is provided on the cathode contact region. The cathode electrode 116 is electrically connected to an outside cathode power 130. In addition, the substrate 100 is earthed using a p⁺ substrate contact region 110 and a substrate electrode 112. The p⁺ substrate contact region 110 and the substrate electrode 112 contacting the substrate 100 are formed near a surface of the isolation layer 108. The cathode electrode 116 and the substrate electrode 112 may be include, for example, a metal silicide in order to use the CMOS process.

An insulating layer 118 illustrated in FIG. 3A is buried at a predetermined depth and at predetermined intervals between the substrate contact region 110 and the first conductive film 126. The insulating layer 118 may be include, for example, a silicon oxide layer which is relatively insensitive to a charge trap. First doped regions 104 are formed in the n-type well 102 between the substrate contact region 110 and the insulating layer 118 to reduce the drift resistor (R2) caused by a current. The first doped region 104 is doped with an n-type impurity. In some embodiments of the present invention, a doping concentration of the n-type impurity is higher than that of the well 102 and is lower than that of the cathode contact region 114.

In some embodiments of the present invention, a second doped region 106 is further formed in the n-type well 102 between the first doped regions 104. The second doped region 106 is similar to the first doped regions 104. The second doped region 106 may be available according to a rated voltage or a manufacturing process of the schottky diode. Generally, the second doped region 106 may be available below a doping concentration of 1018 atoms/cm².

A high-voltage insulating film 120 is formed at one side or both sides of the first conductive film 126. The high-voltage insulating film 120 is interposed between the substrate 100 including the well 102 and a conductive electrode 122. The conductive electrode 122 may include, for example, polysilicon. The polysilicon can be formed using a CMOS process. A second conductive film 124 is formed on the conductive electrode 122. The second conductive film 124 may include, for example, a metal silicide like the first conductive film.

The first and second conductive films 126 and 124 are anode electrodes having similar electric potential values. The first and second conductive films 126 and 124 are electrically connected to an outside anode power 128. The schottky diode (D) and a conductive electrode stricture (M) are connected to the anode power 128 so as to have similar electric potential. In some embodiments of the present invention, when an identical electric potential is applied, a depletion region in the n-type well 102 is expanded by the first conductive film 126 of the schottky diode (D) and the conductive electrode 122 of the conductive electrode structure (M). When the depletion region is expanded, the drift resistor (R2) caused by a current can be reduced.

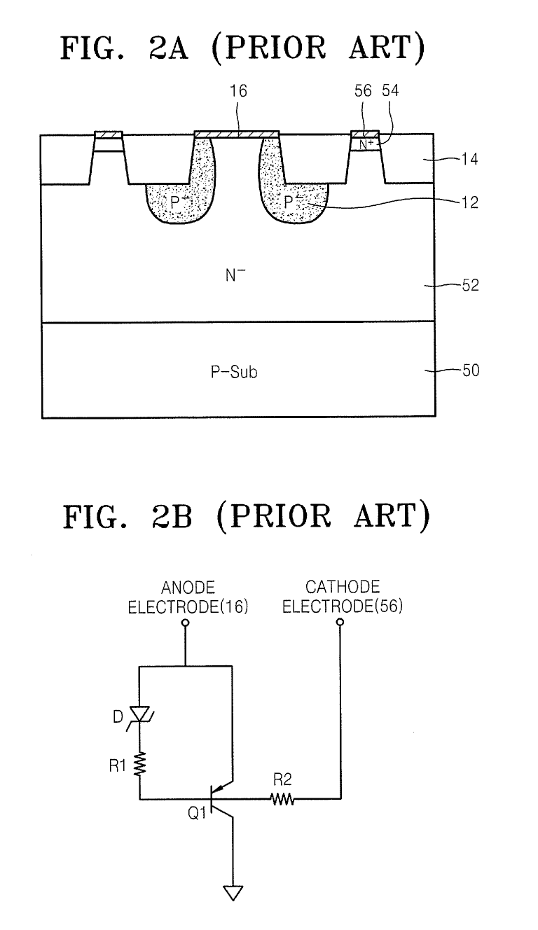

When the conductive electrode 122 of the conductive electrode structure (M), for example, a polysilicon electrode is formed on at least one side of the schottky diode (D), the following effects may be obtained. First, the schottky diode (D) and the conductive electrode structure (M) may have very similar and possibly identical electric potential so that a field concentration effect may be reduced by reducing an electric field at the edge of the first conductive film 126. Since the electric effect is reduced by the conductive electrode structure (M), the conventional p-type impurity region 12 illustrated in Figure may not be necessary to reduce the electric effect. Therefore, the parasitic transistor (Q1) illustrated in FIG. 2B does not occur, and the pinched resistor (R1) is reduced so that the stable schottky diode (D) can be formed. Furthermore, when a forward voltage is applied, a carrier such as an electron is accumulated on the high-voltage insulating film 120 of the conductive electrode structure (M) and a surface of the n-type well 102 so that the pinched resistor (R1) is more reduced.

Referring now to FIG. 4, a partial cross-section illustrating the reason why an insulating layer described in FIG. 3A is present according to some embodiments of the present invention. Accordingly, FIG. 4 illustrates a structure for a high-voltage schottky diode according to FIG. 3A without the insulating layer.

As illustrated in FIG. 4, the conductive electrode 122 is formed by patterning a conductive electrode material layer (not shown) placed on the high-voltage insulating film 120. However, the end (d) of the high-voltage insulating film 120 may be thinned during the patterning process. The end (d) can be easily broken by mechanical impact or electric impact. Therefore, the insulating layer 118 illustrated in FIG. 3A is formed at the end (d) to reduce the likelihood that the insulating layer 120 is broken.

A portion of the high-voltage insulating film 120 may be removed in order to form the n⁺ contact region 114 having a high impurity concentration. Since the insulating layer 118 already defines the contact region 114, the high-voltage insulating film 120 can be removed with less precision. Furthermore, a process margin can be secured by the insulating layer 118. A spacer 132 is formed, and the conductive electrode 122 and the first and second conductive films 126 and 124 are etched using the process margin.

The structure for the high-voltage schottky diode may reduce the likelihood that the parasitic transistor will be generated and may improve a current driving capability by disposing the conductive electrode at the both sides of the schottky diode and on the substrate. Furthermore, the likelihood of breaking the high-voltage insulating layer may be reduced and the process margin for ion implantation may be sufficiently secured by burying the insulating layer between the conductive electrode and the cathode electrode.

In the drawings and specification, there have been disclosed typical embodiments of the invention and, although specific terms are employed, they are used in a generic and descriptive sense only and not for purposes of limitation, the scope of the invention being set forth in the following claims.

That which is claimed is:

1. A high-voltage schottky diode, comprising:
a first conductivity type semiconductor substrate;
a second conductivity type well region defined by the substrate;
a first conductive film on a surface of the substrate including the well;
a conductive electrode on at least one side of the first conductive film above the substrate including the well;
an insulating film between the conductive electrode and the substrate; and
a cathode contact region outside the conductive electrode remote from the first conductive film, the cathode contact region being doped with high concentration impurities having a second conductive type.

2. The diode of claim 1, wherein the first conductive film comprises a metal silicide.

3. The diode of claim 1, further comprising a second conductive film on the conductive electrode, wherein the first and second conductive films are anode electrodes having a similar electric potential value.

4. The diode of claim 3, wherein the first and second conductive films comprise a metal silicide.

5. The diode of claim 1, wherein the conductive electrode comprises polysilicon.

6. The diode of claim 1, further comprising a cathode electrode on the cathode contact region.

7. The diode of claim 1, wherein a first doped region is in the well under the cathode contact region and is doped with impurities having the second conductive type such that a doping concentration of the first doped region is higher than that of the well and lower than that of the cathode contact region.

8. The diode of claim 1, further comprising:
a second doped region in the well under the first conductive film and the conductive electrode, wherein the second doped region is doped with impurities having the second conductive type such that a doping concentration of the second doped region is higher than that of the well and lower than that of the cathode contact region.

9. The diode of claim 7, wherein the doping concentration is lower than 1018 atoms/cm².

10. The diode of claim 8, wherein the doping concentration is lower than 1018 atoms/cm2.

11. The diode of claim 1, further comprising an insulating layer between the conductive electrode and the cathode contact region.

12. The diode of claim 11, wherein the insulating layer comprises a silicon oxide layer.

13. The diode of claim 1, further comprising an isolation layer isolating the well and the substrate from the cathode contact region.

14. The diode of claim 13, further comprising a substrate contact region outside the isolation layer at an opposite side of the cathode contact region, the substrate contact region being doped with high concentration impurities having the first conductivity type.

15. A high-voltage schottky diode, comprising:
a first conductivity type semiconductor substrate;
a second conductivity type well defined on an upper portion of the substrate;
a first conductive film on a surface of the substrate including the well;
a conductive electrode on at least both sides of the first conductive film above the substrate including the well;
an insulating film between the conductive electrode and the substrate;
a cathode contact region outside the conductive electrode remote from the first conductive film, the cathode contact region being doped with high concentration impurities having the second conductivity type; and
an insulating layer on the substrate between the conductive electrode and the cathode contact region for device isolation.

16. The diode of claim 15, further comprising a second conductive film on the conductive electrode, wherein the first and second conductive films are anode electrodes having a similar electric potential value.

17. The diode of claim 16, wherein the first and second conductive films comprise a metal silicide.

18. The diode of claim 15, wherein the conductive electrode comprises polysilicon.

19. The diode of claim 15, wherein a first doped region is in the well under the cathode contact region and is doped with impurities having the second conductivity type such that a doping concentration of the first doped region is higher than that of the well and lower than that of the cathode contact region.

20. The diode of claim 15, further comprising a second doped region in the well under the first conductive film and the conductive electrode, wherein the second doped region is doped with impurities having the second conductivity type such that a doping concentration of the second doped region is higher than that of the well and lower than that of the cathode contact region.
